(19) United States
(12) Patent Application Publication
(10) Pub. No.: US 2009/0035928 A1
(43) Pub. Date: Feb. 5, 2009

(54) METHOD OF PROCESSING A HIGH-K DIELECTRIC FOR CET SCALING

(76) Inventors: Rama I. Hegde, Austin, TX (US); Srikanth B. Samavedam, Fishkill, NY (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/830,331

(22) Filed: Jul. 30, 2007

(51) Int. Cl. H01L 21/3205

(52) U.S. Cl. 438/591; 257/E21.294

(57) ABSTRACT

A method of making a semiconductor device includes making a gate dielectric with an overlying gate electrode. The semiconductor device is made over a semiconductor layer. A high-k dielectric comprising hafnium zirconate is deposited over the semiconductor layer. The high-k dielectric is annealed at a temperature between 650 degrees Celsius and 850 degrees Celsius in an ambient comprising hydrogen and nitrogen. The gate electrode is formed on the high-k dielectric. The high-k dielectric function is for use in the gate dielectric. One affect is to improve the transistor performance while retaining or even improving the level of gate leakage.

### BACKGROUND

1. Field

This disclosure relates generally to semiconductor devices, and more specifically, to a method of processing a high-k dielectric for capacitance equivalent thickness (CET) scaling.

2. Related Art

Capacitance equivalent thickness (CET) scaling of high-k dielectric material is required for improving high-k semiconductor device performance. Examples of high-k dielectric material can include HfO₂, ZrO₂, HfZrO₄, HfSiO, HfSiON, etc. It has been discovered that physically thinner high-k dielectric (on the order of 15 Å or thinner) is required for continued CET scaling. However, in one example, an optimization of HfZrO₄ thickness (T_{phy}) investigation has shown that the CET is higher when T_{phy} is less than 15 Å. This is because less than 15 Å T_{phy} HfZrO₄ films are non-uniform and more permeable to oxygen diffusion which leads to a thicker interfacial layer.

Accordingly, there is a need for an improved method for overcoming the problems in the art as discussed above.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIGS. 1-3 are cross-sectional views of a semiconductor device during various stages of a method of processing a high-k dielectric for CET scaling according to one embodiment of the present disclosure;

FIG. 4 is a cross-sectional view of a semiconductor device having a high-k dielectric layer formed with the method of processing according to the embodiments of the present disclosure;

FIG. 5 is a graphical representation view illustrating CET versus thickness of a high-k dielectric layer for a number of target thicknesses, in which a first set are not processed according to the embodiments of the present disclosure and a second set are processed according to the embodiments of the present disclosure; and

FIG. 6 is a graphical representation view illustrating equivalent oxide thickness (EOT) versus target physical thickness of a high-k dielectric layer for a number of target thicknesses, in which a first set are not processed according to the embodiments of the present disclosure and a second set are processed according to the embodiments of the present disclosure.

### DETAILED DESCRIPTION

A method of making a semiconductor device includes making a gate dielectric with an overlying gate electrode. The semiconductor device is made over a semiconductor layer. A high-k dielectric comprising hafnium zirconate is deposited over the semiconductor layer. The high-k dielectric is annealed at a temperature between 650 degrees Celsius and 850 degrees Celsius in an ambient comprising hydrogen and nitrogen. The gate electrode is formed on the high-k dielectric. The high-k dielectric function is for use in the gate dielectric. One affect is to improve the transistor performance while retaining or even improving the level of gate leakage.

A method according to the embodiments of the present disclosure includes the formation of a physically thinner (15 Å or thinner) high-k dielectric with desired thin film dielectric properties for CET scaling. The method includes a process that etches a high-k material and simultaneously helps to thin an interfacial layer (IL) so that a desired CET scaling benefit can be obtained. In one embodiment, the desired CET scaling is maximized.

According to one embodiment of the present disclosure, a method comprises (1) depositing or forming a relatively thick (thicker than 15 Å) high-k dielectric layer so that the starting high-k film is continuous and more uniform; (2) perform a controlled removal of the starting high-k dielectric layer by higher temperature post deposition annealing in an ambient containing nitrogen and hydrogen such as ammonia (NH₃), pyridine (C₅H₅N), hydrazine (N₂H₄), etc.; and (3) vary anneal temperature (650-850 C) and time (50-200 s) to obtain an etch rate and thus tune a final thickness of the high-k dielectric for CET scaling.

The semiconductor substrate described herein can be any semiconductor material or combinations of materials, such as gallium arsenide, silicon germanium, silicon-on-insulator (SOI), silicon, monocrystalline silicon, the like, and combinations of the above.

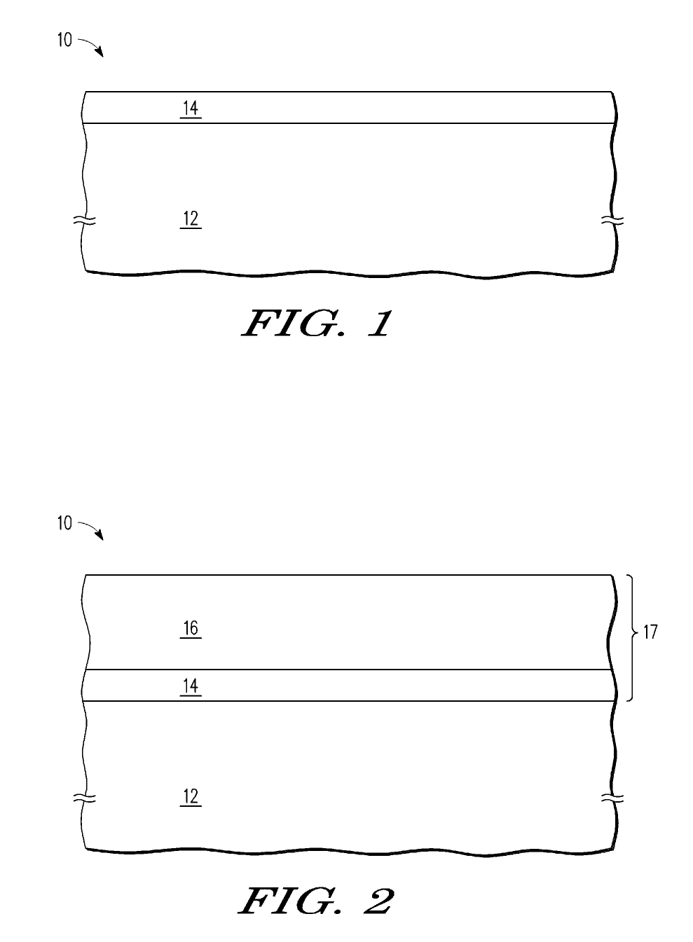

FIGS. 1-3 are cross-sectional views of a semiconductor device 10 during various stages of a method of processing a high-k dielectric for CET scaling according to one embodiment of the present disclosure. In one embodiment, semiconductor substrate 12 is provided, the substrate comprising a silicon substrate having an interfacial layer (IL) 14 of silicon oxide overlying a surface of the substrate 12. In FIG. 2, a high-k dielectric layer 16 is formed overlying the interfacial layer 14. In one embodiment, the high-k dielectric layer 16 comprises HfZrO₄. The high-k dielectric layer 16 and the interfacial layer 14 are together referred to by reference numeral 17.

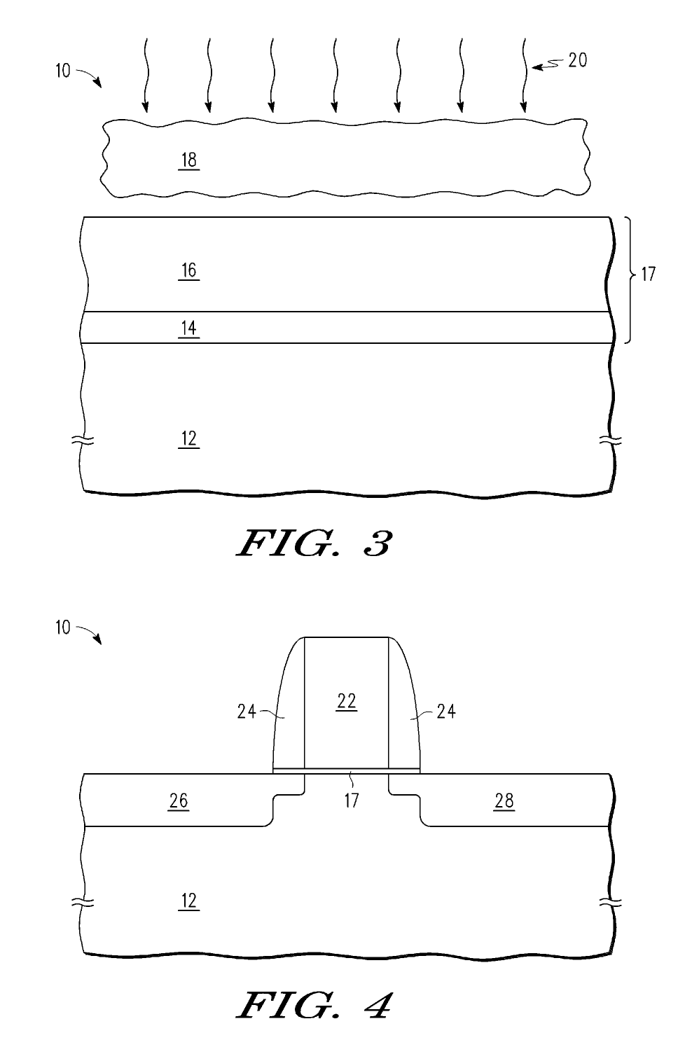

In FIG. 3, the semiconductor device 10 is processed by exposure to an ambient 18 and an anneal 20 for a given time duration. In one embodiment, the ambient 18 comprises an ambient containing nitrogen and hydrogen. For example, in one embodiment, the ambient containing nitrogen and hydrogen comprises one or more of ammonia (NH₃), pyridine (C₅H₅N), hydrazine (N₂H₄), or other suitable nitrogen and hydrogen ambient. Anneal 20 comprises, for example, an anneal temperature on the order of 650° C. to 850° C. (650-850° C.) and having a time duration on the order of 50 seconds to 200 seconds (50-200 s). The combination of the ambient and anneal provide for a desired high-k dielectric thickness reduction rate, thus enabling an ability to tune a final thickness of the high-k dielectric for CET scaling.

High temperature post deposition annealing in nitrogen and hydrogen containing ambient is beneficial for a number of reasons. For one, the high temperature post deposition annealing in nitrogen and hydrogen containing ambient incorporates a controlled amount of nitrogen and reduces a possibly of oxygen vacancy and trap density in the high-k dielectric. For another reason, the high temperature post deposition annealing in nitrogen and hydrogen containing ambient densifies the high-k dielectric layer. Furthermore, the high temperature post deposition annealing in nitrogen and hydrogen containing ambient inhibits interfacial oxide growth. More importantly, the high temperature post deposition annealing in nitrogen and hydrogen containing ambient chemically removes (i.e., etches) a desired level of the high-k layer in a controlled fashion. Accordingly, this chemical etching process results in thinner, dense, and uniform high-k layer with thinner interfacial layer for CET scaling.

FIG. 4 is a cross-sectional view of a semiconductor device 10 having a high-k dielectric layer 17 formed with the method of processing according to the embodiments of the present disclosure. In particular, FIG. 4 is a partial cross-sectional view the portion of the semiconductor device 10 of FIG. 3 during further processing in the manufacture thereof, the semiconductor device featuring a high-k dielectric layer according to one embodiment of the present disclosure. Further processing includes formation of gate electrode 22, sidewall spacers 24, source/drain regions (26,28), and silicide regions (not shown), using any suitable techniques for forming the same, and according to the requirements of the desired semiconductor device application.

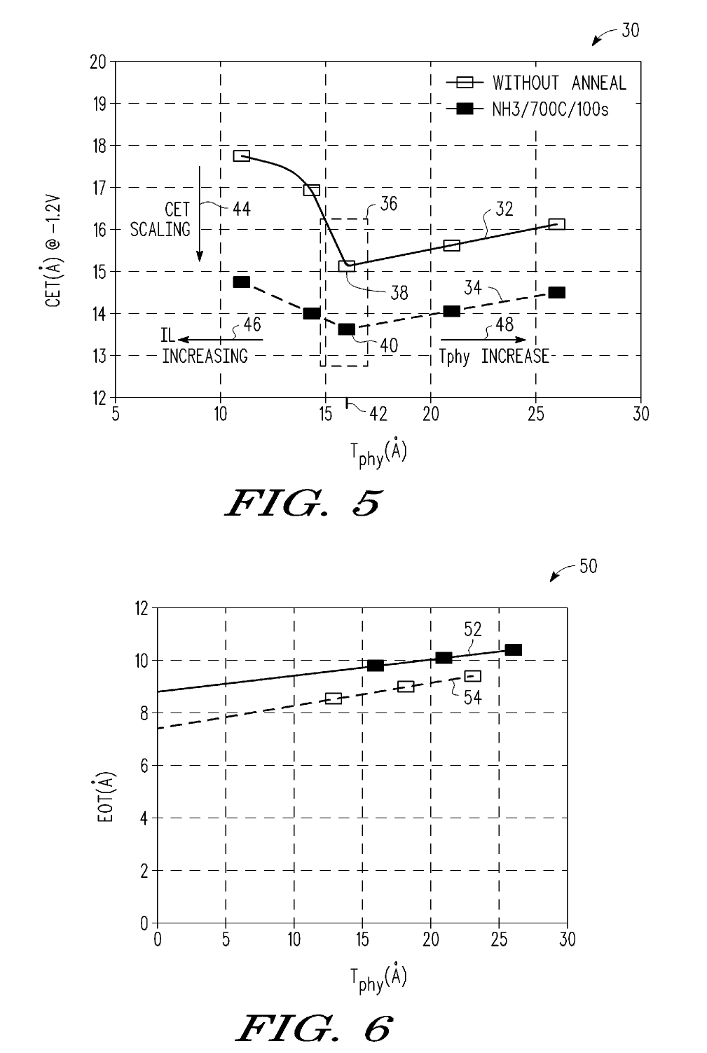

FIG. 5 is a graphical representation view 30 illustrating CET (on the vertical axis) versus thickness of a high-k dielectric layer (on the horizontal axis) for a number of target thicknesses, in which a first set 32 are not processed according to the embodiments of the present disclosure and a second set 34 are processed according to the embodiments of the present disclosure. The CET thickness data for graphical view 30 was determined using a gate voltage equal to 1.2 volts. The CET thickness data could have been obtained for other gate voltages also. With reference now to the window indicated by reference numeral 36, contained within window 36 are data points 38 and 40. Data point 38 represents a thickness of HfZrO₄ obtained without processing according to the embodiments of the present disclosure. Data point 40 represents a thickness of HfZrO₄ obtained with processing according to the embodiments of the present disclosure. The physical thickness T_{phy} as indicated by reference numeral 42 is approximately 16 Å, and representative of a maximum CET benefit thickness.

CET scaling is graphically represented by an arrow indicated by reference numeral 44. While the physical thickness of data points 38 and 40 are similar at the maximum CET benefit thickness 42, note that the CET for data point 38 is on the order of more than 15 Å, or approximately 15 Å, while the CET for data point 40 is on the order of less than 14 Å, or approximately 13.5 Å. Recall that data point 38 is representative of a high-k dielectric that was obtained without processing according to the embodiments of the present disclosure. In addition, data point 40 is representative of a high-k dielectric that was obtained with processing according to the embodiments of the present disclosure. Accordingly, an amount of CET scaling on the order of approximately 1.5 Å is obtained between data point 38 and data point 40. In addition, of the data points 34 shown in FIG. 5, the physical thickness T_{phy} indicated by reference numeral 42 represents the maximum CET benefit thickness obtained by the new process with respect to the CET benefit obtained among the other data points 34.

Interfacial layer (IL) increasing thickness is graphically represented by an arrow indicated by reference numeral 46. In other words, at physical thicknesses less than the maximum CET benefit thickness 42, it was observed that the interfacial layer thickness increases with decreasing overall physical thickness of the combined high-k dielectric layer and interfacial layer thickness. Such an increasing in the interfacial layer thickness is undesirable and thus total physical thicknesses that decrease below the maximum CET benefit thickness 42 and outside of window 36 are not preferred. Furthermore, for decreasing thicknesses less than the maximum CET benefit thickness 42 and outside of window 36, the interfacial layer thickness dominates a greater and greater percentage of the total thickness (in comparison to the percentage of the total thickness attributable to the high-k dielectric). The range (minimum T_{phy}, maximum T_{phy}) of physical thickness for window 36 is selected according to the specific requirements of a given semiconductor device application. The range of window 36 depends on the Hf content in the hafnium zirconate film. If a different high-k dielectric layer is used, one will obtain different limits on window 36. The purpose of this data is to illustrate the limitations of traditional thickness scaling to lower CET.

In addition, physical layer increasing thickness is graphically represented by an arrow indicated by reference numeral 48. In other words, at physical thicknesses greater than the maximum CET benefit thickness 42, it was observed that while the physical thickness increased, the interfacial layer thickness remained approximately the same with increasing overall physical thickness of the combined high-k dielectric layer and interfacial layer thickness. Such a maintaining of the interfacial layer thickness to a substantially constant thickness is desirable and thus total physical thicknesses increases above the maximum CET benefit thickness 42 and outside of window 36 is predominately due to increase in the high-k dielectric thickness.

FIG. 6 is a graphical representation view 50 illustrating equivalent oxide thickness (EOT) (on the vertical axis) versus target physical thickness of a high-k dielectric layer (on the horizontal axis) for a number of target thicknesses, in which a first set 52 are not processed according to the embodiments of the present disclosure and a second set 54 are processed according to the embodiments of the present disclosure. It can be observed from the graphical representation view 50, with an appropriate curve fitting of data points, that for the physical thickness of 0 Å of the high-k dielectric layer for the first set 52, the EOT of the IL layer is on the order of 9 Å. For the physical thickness of 0 Å of the high-k dielectric layer of the second set 54, the EOT of the IL layer is on the order of 7.5 Å. The difference of approximately 1.5 Å is representative of the approximate IL layer thickness reduction for the high-k dielectric layer processed with the embodiments of the present disclosure. Also, illustrated data points (indicated by open rectangles on line 54) of the high-k dielectric layer processed with the embodiments of the present disclosure are physically thinner than corresponding ones of data points (indicated by filled rectangles on line 52) of the high-k dielectric layer not processed by the embodiments of the present disclosure.

By now it should be appreciated that there has been provided a method of making a semiconductor device on a semiconductor layer, comprising: forming a gate dielectric wherein forming the gate dielectric comprises depositing a high-k dielectric comprising hafnium zirconate over the semiconductor layer; annealing the high-k dielectric at a temperature between 650 degrees Celsius and 850 degrees Celsius in an ambient comprising hydrogen and nitrogen; and forming a gate electrode over the high-k dielectric. The step of annealing is further characterized by the ambient comprising one of a group consisting of ammonia, pyridine, and hydrazine. In another embodiment, the step of depositing is further characterized by the hafnium zirconate comprising HfZrO₄. In a further embodiment, the step of annealing is characterized by the temperature not exceeding 800 degrees Celsius. In yet another embodiment, the step of annealing is further characterized by the temperature not exceeding 750 degrees Celsius. In a still further embodiment, the step of annealing is characterized by the temperature being about 700 degrees Celsius.

In another embodiment, the step of forming a gate comprises depositing one of group consisting of titanium nitride, tantalum carbide, molybdenum nitride, and molybdenum oxynitride. The step of annealing is further characterized by the high-k dielectric being continuous after the step of annealing.

In another embodiment, the step of forming the gate dielectric further comprises forming an interfacial oxide of a first thickness on the semiconductor layer prior to performing the step of depositing. The step of annealing reduces the interfacial oxide to a second thickness less than the first thickness, wherein the second thickness is less than 10 Angstroms. In addition, the step of annealing is further characterized by reducing a thickness of the high-k dielectric.

In another embodiment, a method of forming a semiconductor device on a semiconductor layer, comprises: forming an interfacial oxide directly on the semiconductor layer; depositing a layer of hafnium zirconate directly on the interfacial oxide layer; annealing the hafnium zirconate at a temperature between 650 degrees Celsius and 750 degrees Celsius in an ambient comprising hydrogen and nitrogen; and forming a gate electrode over the hafnium zirconate. The step of annealing is further characterized by the ambient comprising one of a group consisting of ammonia, pyridine, and hydrazine. The step of depositing is further characterized by the hafnium zirconate comprising HfZrO₄. The step of annealing is further characterized as reducing a thickness of the interfacial layer and a thickness of the hafnium zirconate. The step of forming the interfacial oxide is further characterized by the interfacial oxide comprising silicon oxide. Furthermore, the step of reducing the thickness of the interfacial oxide reduces the thickness of the interfacial oxide to less than 10 Angstroms.

In one embodiment, a method of forming a semiconductor device on a layer of silicon comprises: forming a silicon dioxide layer directly on the semiconductor layer, wherein the silicon dioxide layer has a thickness; depositing a hafnium zirconate layer directly on the silicon dioxide layer, wherein the hafnium zirconate layer has a thickness, annealing the hafnium zirconate layer at a temperature between about 650 degrees Celsius and about 750 degrees in an ambient comprising hydrogen and nitrogen which reduces the thickness of the silicon dioxide layer and the thickness of the hafnium zirconate layer; and forming a gate electrode over the hafnium zirconate layer. In one embodiment, the step of depositing the hafnium zirconate layer is further characterized by the hafnium zirconate layer comprising HfZrO₄; and the step of annealing the hafnium zirconate layer is further characterized by applying one of a group consisting of ammonia, pyridine, and hydrazine. In another embodiment, the step of annealing is further characterized by the temperature being about 700 degrees Celsius.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, the method can be applied to high-k dielectrics used in highly scaled CMOS, 3D integration, MRAM, embedded NVM, embedded SRAM, and other semiconductor device applications. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method of making a semiconductor device on a semiconductor layer, comprising:
forming a gate dielectric wherein the forming the gate dielectric comprises depositing a high-k dielectric comprising hafnium zirconate over the semiconductor layer,
annealing the high-k dielectric at a temperature between 650 degrees Celsius and 850 degrees Celsius in an ambient comprising hydrogen and nitrogen; and
forming a gate electrode over the high-k dielectric.

2. The method of claim 1, wherein the step of annealing is further characterized by the ambient comprising one of a group consisting of ammonia, pyridine, and hydrazine.

3. The method of claim 1, wherein the step of depositing is further characterized by the hafnium zirconate comprising HfZrO₄.

4. The method of claim 1, wherein the step of annealing is further characterized by the temperature not exceeding 800 degrees Celsius.

5. The method of claim 4, wherein the step of annealing is further characterized by the temperature not exceeding 750 degrees Celsius.

6. The method of claim 5, wherein the step of annealing is further characterized by the temperature being about 700 degrees Celsius.

7. The method of claim 1, wherein the step of forming a gate comprises depositing one of group consisting of titanium nitride, tantalum carbide, molybdenum nitride, and molybdenum oxynitride.

8. The method of claim 1, wherein the step of annealing is further characterized by the high-k dielectric being continuous after the step of annealing.

9. The method of claim 1, wherein the step of forming the gate dielectric further comprises forming an interfacial oxide of a first thickness on the semiconductor layer prior to performing the step of depositing.

10. The method of claim 9, wherein the step of annealing reduces the interfacial oxide to a second thickness less than the first thickness, wherein the second thickness is less than 10 Angstroms.

11. The method of claim 10, wherein the step of annealing is further characterized by reducing a thickness of the high-k dielectric.

12. A method of forming a semiconductor device on a semiconductor layer, comprising:
forming an interfacial oxide directly on the semiconductor layer;
depositing a layer of hafnium zirconate directly on the interfacial oxide layer,
annealing the hafnium zirconate at a temperature between 650 degrees Celsius and 750 degrees Celsius in an ambient comprising hydrogen and nitrogen; and
forming a gate electrode over the hafnium zirconate.

13. The method of claim 12, wherein the step of annealing is further characterized by the ambient comprising one of a group consisting of ammonia, pyridine, and hydrazine.

14. The method of claim 13, wherein the step of depositing is further characterized by the hafnium zirconate comprising HfZrO₄.

15. The method of claim 14, wherein the step of annealing is further characterized as reducing a thickness of the interfacial layer and a thickness of the hafnium zirconate.

16. The method of claim 15, wherein the step of forming the interfacial oxide is further characterized by the interfacial oxide comprising silicon oxide.

17. The method of claim 16, wherein the step of reducing the thickness of the interfacial oxide reduces the thickness of the interfacial oxide to less than 10 Angstroms.

18. A method of forming a semiconductor device on a layer of silicon, comprising:
forming a silicon dioxide layer directly on the semiconductor layer, wherein the silicon dioxide layer has a thickness;
depositing a hafnium zirconate layer directly on the silicon dioxide layer, wherein the hafnium zirconate layer has a thickness,
annealing the hafnium zirconate layer at a temperature between about 650 degrees Celsius and about 750 degrees in an ambient comprising hydrogen and nitrogen which reduces the thickness of the silicon dioxide layer and the thickness of the hafnium zirconate layer; and
forming a gate electrode over the hafnium zirconate layer.

19. The method of claim 18, wherein:
the step of depositing the hafnium zirconate layer is further characterized by the hafnium zirconate layer comprising HfZrO₄; and
the step of annealing the hafnium zirconate layer is further characterized by applying one of a group consisting of ammonia, pyridine, and hydrazine; and

20. The method of claim 18, wherein the step of annealing is further characterized by the temperature being about 700 degrees Celsius.
